(19) United States
(12) Patent Application Publication
(10) Pub. No.: US 2013/0043500 A1
(43) Pub. Date: Feb. 21, 2013

(54) LIGHT EMITTING DEVICE

(71) Applicant: Panasonic Corporation, Osaka (JP)

(72) Inventor: Kenji ORITA, Osaka (JP)

(73) Assignee: PANASONIC CORPORATION, Osaka (JP)

(21) Appl. No.: 13/656,351

(22) Filed: Oct. 19, 2012

Related U.S. Application Data
(63) Continuation of application No. PCT/JP2010/005415, filed on Sep. 2, 2010.

(30) Foreign Application Priority Data
Apr. 21, 2010 (JP) 2010-097585

(51) Int. Cl. H01L 33/44

(52) U.S. Cl. 257/98; 257/E33.061

(57) ABSTRACT

A light emitting device includes: a semiconductor multilayer film formed on a principal surface of a substrate, and including an active layer configured to generate light at a first wavelength; and a fluorescent material layer formed on the semiconductor multilayer film, and forming a first two-dimensional periodic structure. The fluorescent material layer generates light at a second wavelength by being excited by the first wavelength light, the semiconductor multilayer film has an optical waveguide through which the first wavelength light and the second wavelength light are guided, and the light radiated from an end face of the optical waveguide includes a higher proportion of light having an electric field oriented in a direction horizontal to the principal surface than a proportion of light having an electric field oriented in a direction perpendicular to the principal surface.

### CROSS-REFERENCE TO RELATED APPLICATIONS

This is a continuation of PCT International Application PCT/JP2010/005415 filed on Sep. 2, 2010, which claims priority to Japanese Patent Application No. 2010-097585 filed on Apr. 21, 2010. The disclosures of these applications including the specifications, the drawings, and the claims are hereby incorporated by reference in their entirety.

### BACKGROUND

The present disclosure relates to light emitting devices, and more particularly relates to a light emitting device for use in, e.g., a backlight light source device.

In recent years, the market for liquid crystal displays including flat-screen televisions has rapidly grown. A liquid crystal display includes a liquid crystal panel serving as a transmissive light modulator element, and a light source device disposed on the back surface of the liquid crystal panel to illuminate the liquid crystal panel. The liquid crystal panel forms an image by controlling the transmittance of light radiated from the light source device. A cold cathode fluorescent lamp (CCFL) has been used as a light source of the light source device; however, in recent years, with the trend toward energy conservation, light emitting diode (LED) light source devices using LED elements are being developed. LED light source devices using an LED as a light source can be classified mainly into two types. The first type is a direct-lit LED light source device in which LED elements are two-dimensionally arranged immediately behind a display screen, and the second type is an edge-lit LED light source device in which LED elements are arranged in lateral directions of the liquid crystal panel, and which illuminates the liquid crystal panel from the back of the liquid crystal panel using a light guide plate. Currently, direct-lit LED light source devices are generally used; however, in order to satisfy the need for reducing the thicknesses of liquid crystal displays, edge-lit LED light source devices are being developed.

A conventional LED element for liquid crystal display includes a yellow fluorescent material having a fluorescence center wavelength of about 570 nm and covering an LED chip emitting blue light having a center wavelength of about 440 nm. Blue light is radiated by driving the LED chip, and the radiated blue light is absorbed by the fluorescent material, thereby radiating yellow light. Blue and yellow are complementary colors, and thus, an LED element functioning as a white light source can be achieved.

### SUMMARY

However, when a conventional LED element is used as an edge-lit LED light source device of a liquid crystal display, this prevents light emitting from the LED element from efficiently entering a light guide plate, and thus, the efficiency of utilizing the light emitting from the LED element is low. A method is described wherein the surface of an LED element is covered with a cylindrical lens serving as a scattering lens to enhance the efficiency of light incidence on a light guide plate (see, e.g., Japanese Patent Publication No. 2009-158274). However, in this case, the thickness of the light guide plate cannot be reduced. The angle at which light is radiated from the surface of the LED element is a so-called Lambertian angle, and light beams having a full width at half maximum divergence angle of 120° exit therefrom. In order to more efficiently concentrate the exiting light beams having such radiation characteristics on a lens, the size of the lens needs to be 5-10 times the size of the LED element. The size of the LED element is about 0.5 mm×0.5 mm, and thus, the size of the lens needs to be about 2.5-5 mm. In contrast, in order to efficiently guide light beams to the light guide plate, the thickness of the light guide plate needs to be increased to about the size of the lens. Therefore, the thickness of the light guide plate needs to be about 2.5-5 mm, and the degree of reduction in the thickness of the liquid crystal panel is limited.

Light radiated from a CCFL and an LED chip corresponds to spontaneous emission light, and thus, a polarization direction of the light is random. Polarization is utilized to control the transmittance of light through a liquid crystal panel, and thus, a polarizing plate is placed toward the light entrance side of the liquid crystal panel, and only required specific polarized light enters the liquid crystal panel. Specifically, polarized light at an angle of 90 degrees from the required polarization direction are absorbed or reflected by the polarizing plate. The transmittance of the required polarized light through the polarizing plate is substantially 100%, and the transmittance of the polarized light at an angle of 90 degrees from the required polarization direction through the polarizing plate is substantially 0%. When the angle from the specific polarization direction is 0, the transmittance of light at a polarizing angle up to 90 degrees from the required polarization direction is cos 0×100%. When the polarization direction is random, only about 50% of light incident on the polarizing plate passes through the polarizing plate, and enters the liquid crystal panel. In this case, the efficiency of light utilization is up to 50%, because 50% of light generated by a light source device is removed by the polarizing plate, and the remaining light is utilized for liquid crystal display. As such, the amount of energy substantially equivalent to the amount of light energy utilized for liquid crystal display is not effectively utilized.

An object of the present disclosure is to solve the problems, and provide a light emitting device which, when used as a light source device, has high efficiency of emitted light utilization.

Specifically, an example light emitting device includes: a semiconductor multilayer film formed on a principal surface of a substrate, and including an active layer configured to generate light at a first wavelength; and a fluorescent material layer formed on the semiconductor multilayer film, and forming a first two-dimensional periodic structure. The fluorescent material layer generates light at a second wavelength by being excited by the first wavelength light, the semiconductor multilayer film has an optical waveguide through which the first wavelength light and the second wavelength light are guided, and the first wavelength light and the second wavelength light which are radiated from an end face of the optical waveguide include a higher proportion of light having an electric field oriented in a direction horizontal to the principal surface than a proportion of light having an electric field oriented in a direction perpendicular to the principal surface.

The example light emitting device can confine the first wavelength light and the second wavelength light in the optical waveguide, and thus, the vertical radiation angle and the horizontal radiation angle can be reduced. Therefore, light can be efficiently coupled to a light guide plate, and can be efficiently collimated by a small lens. This can enhance the efficiency of light utilization.

In the example light emitting device, the first two-dimensional periodic structure may form a photonic band gap for the second wavelength light having an electric field oriented in a direction perpendicular to the principal surface. With this configuration, there does not exist a mode of the second wavelength light having an electric field oriented in a direction perpendicular to the principal surface of the substrate. Thus, only spontaneous emission light and stimulated emission light having an electric field oriented in a direction parallel to the principal surface of the substrate are produced inside the optical waveguide. As a result, a light emitting device configured to radiate light in a specific polarization direction can be achieved.

In the example light emitting device, a portion of the fluorescent material layer formed over a central portion of the optical waveguide may form the first two-dimensional periodic structure, a portion of the fluorescent material layer formed over an outer portion of the optical waveguide may form a second two-dimensional periodic structure, and periods of the first and second two-dimensional periodic structures, or sizes or shapes of base units forming the periodic structures may be different from each other. In this case, the second two-dimensional periodic structure may form a photonic band gap for the second wavelength light having an electric field oriented in a direction parallel to the principal surface. With this configuration, the TE-polarized second wavelength light can be more efficiently confined in the optical waveguide.

The example light emitting device may further include: a transparent electrode formed between the semiconductor multilayer film and the fluorescent material layer.

When the light emitting device of the present disclosure is used as a light source device, the light emitting device can provide high efficiency of emitted light utilization.

### BRIEF DESCRIPTION OF THE DRAWINGS

FIGS. 1A-1D are perspective views sequentially illustrating process steps in a method for fabricating a light emitting device according to an embodiment.

FIG. 2 is a plan view illustrating a two-dimensional periodic structure of a fluorescent material layer.

FIGS. 3A and 3B illustrate an operation principle of a light emitting device according to the embodiment, FIG. 3A is a cross-sectional view of the light emitting device along an end face thereof, and FIG. 3B is a cross-sectional view of the light emitting device along an optical waveguide.

FIG. 4 is a graph illustrating a photonic band structure of a photonic crystal formed by the fluorescent material layer.

FIGS. 5A is a profile illustrating the distribution of light in a semiconductor multilayer film at a wavelength of 440 nm, and FIG. 5B is a profile illustrating the distribution of light in a semiconductor multilayer film at a wavelength of 570 nm.

FIG. 6 is a plan view illustrating a variation of a two-dimensional periodic structure of the fluorescent material layer.

FIG. 7 is a graph illustrating a photonic band structure of the fluorescent material layer formed in an outer portion of the optical waveguide.

FIG. 8 is a diagram illustrating an example in which the light emitting device according to the embodiment is used as a backlight for a liquid crystal panel.

FIG. 9 is a diagram illustrating an example in which the light emitting device according to the embodiment is used as a light source for a projector.

### DETAILED DESCRIPTION

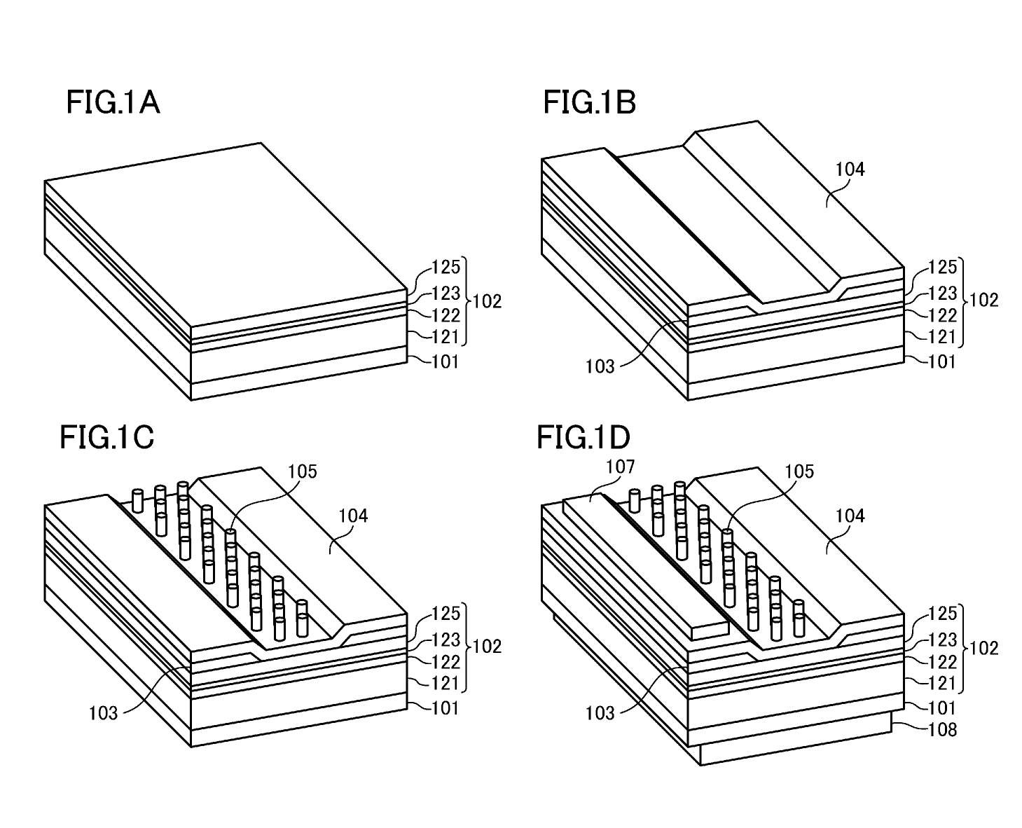

Initially, the structure of a light emitting device according to an embodiment and a method for fabricating the same will be described with reference to the drawings. First, as illustrated in FIG. 1A, a semiconductor multilayer film 102 made of a nitride semiconductor is formed on a substrate 101 having a principal surface with a (0001) plane orientation and made of n-type GaN by, e.g., metal organic chemical vapor deposition (MOCVD). The semiconductor multilayer film 102 may include, for example, an n-type cladding layer 121, an active layer 122, a p-side optical guide layer 123, an electron overflow stop (OFS) layer (not shown), and a p-type contact layer 125 which are sequentially formed on the substrate 101. The n-type cladding layer 121 may have a thickness of 1.6 μm, and may be made of n-type Al_{0.8}In_{0.2}N having a silicon (Si) concentration of 5×10¹⁷ cm⁻³. The active layer 122 may have a double quantum well structure in which a 3-nm-thick well layer made of In_{0.25}Ga_{0.85}N and a 7-nm-thick barrier layer made of undoped In_{0.03}Ga_{0.97}N are laminated. In this case, the emission wavelength is about 440 nm. The p-side optical guide layer 123 may be undoped In_{0.02}Ga_{0.98}N with a thickness of 50 nm. The OFS layer may be p-type Al_{0.2}Ga_{0.8}N having a thickness of 10 nm and a Mg concentration of 1×10¹⁹ cm⁻³. The p-type contact layer 125 may be p-type GaN having a thickness of 50 nm and a Mg concentration of 3×10¹⁹ cm⁻³. The compositions, thicknesses, etc., of these layers are examples, and may be appropriately changed.

Next, as illustrated in FIG. 1B, a current confinement layer 103 and a transparent electrode 104 are formed on the semiconductor multilayer film 102. In order to form the current confinement layer 103, a 100-nm-thick silicon dioxide film (SiO₂ film) may be deposited on the semiconductor multilayer film 102 by, e.g., chemical vapor deposition (CVD), and then, an about 4-μm-wide groove may be formed by, e.g., wet etching to expose the p-type contact layer 125. In order to form the transparent electrode 104, an about 100-nm-thick indium tin oxide (ITO) film may be formed by, e.g., sputtering to cover the current confinement layer 103 and be in contact with the p-type contact layer 125 in the opening. When the light emitting device is a superluminescence diode (SLD), the direction in which the groove extends may be inclined about 10° relative to an m-axis ([10-10]) of the substrate 101 made of GaN.

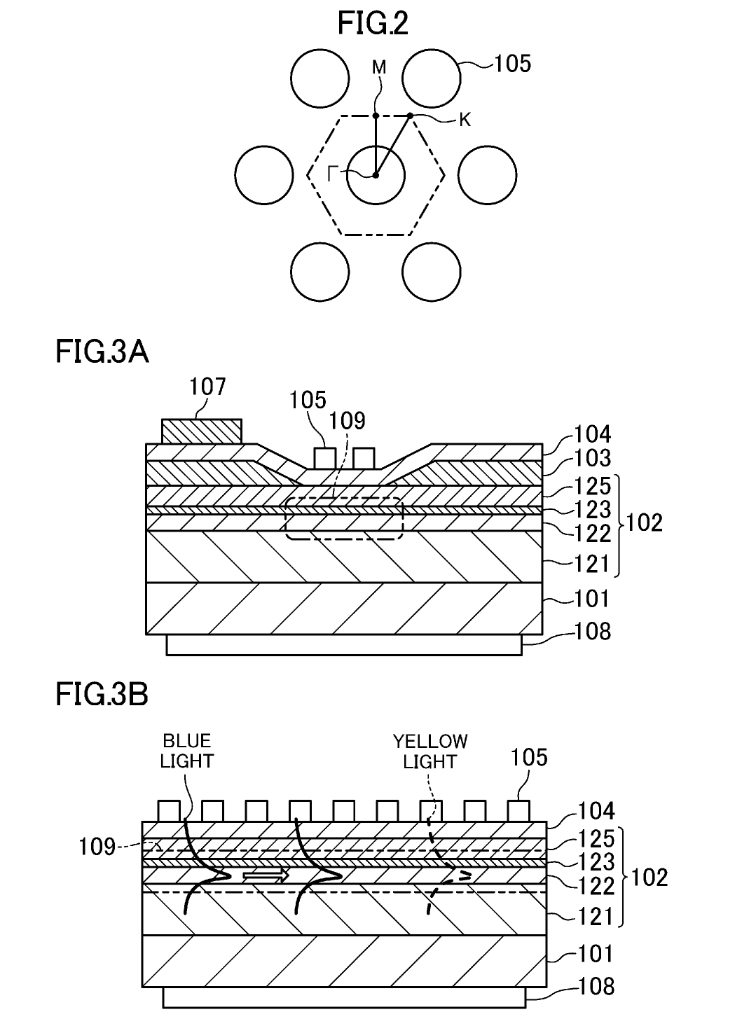

Next, as illustrated in FIG. 1C, a fluorescent material layer 105 made of yttrium aluminum garnet activated by cerium (YAG:Ce) and having, e.g., cylindrical portions is formed. In order to form the fluorescent material layer 105, an about 100-nm-thick fluorescent material may be deposited by, e.g., sputtering, and then, lithography, such as electron beam exposure, and dry etching may be used. The cylindrical portions of the fluorescent material layer 105 may have a diameter 2 r of 128.5 nm, and may be arranged in a triangular lattice with a period a of 257 nm. Furthermore, as illustrated in FIG. 2, the direction from the center of each of the cylindrical portions of the fluorescent material layer 105 toward the M point in a corresponding first Brillouin zone coincides with the direction in which the groove extends.

Next, as illustrated in FIG. 1D, a p-electrode 107 and an n-electrode 108 are formed. The p-electrode 107 may be a multilayer film (Ti/Al/Pt/Au) of titanium (Ti), aluminum (Al), platinum (Pt), and gold (Au) selectively formed on the transparent electrode 104. The n-electrode 108 may be Ti/Al/Pt/Au formed on the back surface of the substrate 101 the thickness of which has been reduced to facilitate dicing the substrate 101.

FIGS. 1A-1D illustrate a single light emitting device; however, a plurality of light emitting devices are actually formed on a wafer, and then, the wafer is singulated into chips by a first cleavage for exposing an m-plane which is a (10-10) plane of the wafer and a second cleavage for exposing an a-plane which is a (11-20) plane of the wafer.

The light emitting device chips including unshown bonding pad regions may each have a width of 200 μm and a length of 800 μm.

Operation of the light emitting device of this embodiment will be described hereinafter with reference to FIGS. 3A and 3B. FIG. 3A illustrates the structure of a cross section of the light emitting device taken along a direction perpendicular to the groove, and FIG. 3B illustrates the structure of a cross section of the light emitting device taken along the groove.

Holes are injected from the p-electrode 107 through the transparent electrode 104 and the p-type contact layer 125 into the active layer 122, and electrons are injected from the n-electrode 108 through the substrate 101 and the n-type cladding layer 121 into the active layer 122. The holes and the electrons are recombined together in a portion of the active layer 122 immediately above which the current confinement layer 103 is not formed, thereby generating spontaneously emitting blue light having a wavelength of about 440 nm. The refractive index of the transparent electrode 104 made of ITO is 2.1, and the refractive index of the current confinement layer 103 made of SiO₂ is 1.46. Therefore, the transparent electrode 104 having a high refractive index serves as a loading layer, thereby forming an optical waveguide 109. Spontaneous emission light coupled to a waveguide mode of the optical waveguide 109 propagates through the interior of the optical waveguide 109.

An increase in the voltage applied between the p-electrode 107 and the n-electrode 108 increases the density of carriers injected into the active layer 122. When the carrier density exceeds the transparency carrier density, emission induced by the active layer 122 is started, and guided light is optically amplified. When the active layer 122 has a quantum well structure, the light amplification factor (optical gain) of TE-polarized light which is guided light having an electric field oriented in a direction parallel to the principal surface of the substrate 101 is higher than that of TM-polarized light which is guided light having an electric field oriented in a direction in which constituent layers of the semiconductor multilayer film 102 are laminated, i.e., in a direction perpendicular to the principal surface of the substrate 101. Therefore, in the optically amplified guided light, the amount of the TE-polarized light is larger than that of the TM-polarized light. Specifically, the ratio of the TE-polarized light to the TM-polarized light, i.e., TE-polarized light/TM-polarized light, (hereinafter referred to as the “TE-polarized light ratio”) is higher than 15.

Light amplification occurs which provides positive feedback of light by edge reflections, and when the optical gain exceeds a threshold value, lasing occurs. In this embodiment, a groove serving as an optical waveguide is inclined 10° relative to the m axis. This reduces the reflectivity (mode reflectivity) of guided light on an optical waveguide end face, thereby reducing lasing. Therefore, a low-coherence superluminescence diode exhibiting low speckle noise is formed.

The fluorescent material layer 105 made of YAG:Ce absorbs optically amplified and propagating blue light. A YAG matrix doped with Ce absorbs blue light, and thus, excitons are generated to allow energy to transfer to Ce which is a luminescent center. Therefore, yellow light derived from Ce and having a wavelength of about 570 nm is generated.

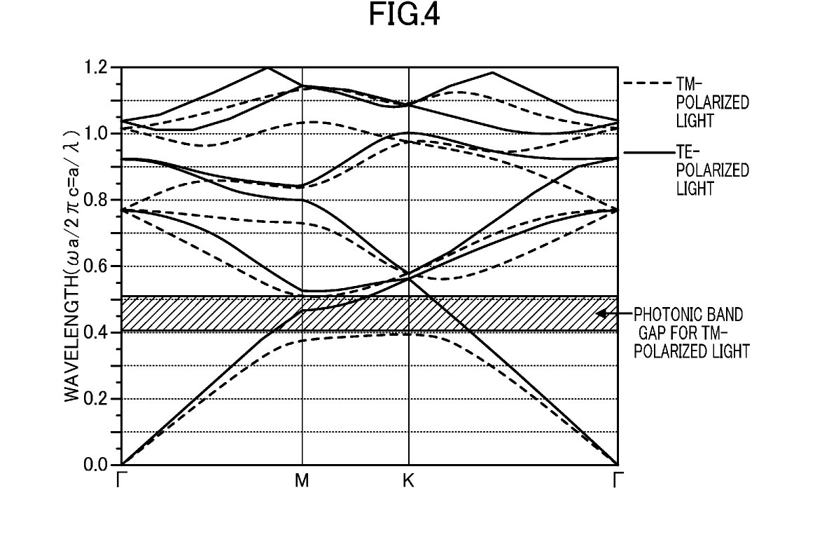

The cylindrical portions of the fluorescent material layer 105 have a two-dimensional periodic structure, and function as a two-dimensional photonic crystal for light emission from excitons. FIG. 4 illustrates results of theoretically calculating the photonic band structure of the two-dimensional photonic crystal relative to light with a wavelength of in a vacuum by plane development. The symbol w denotes the light frequency, and the character c denotes the light velocity in a vacuum. In the calculation, it was assumed that the refractive index of the fluorescent material layer 105 is 2.0, a value r/a obtained by dividing the radius r of each of the cylindrical portions of the fluorescent material layer 105 by the period a is 0.25, and a space among the cylindrical portions of the fluorescent material layers 105 is filled with air with a refractive index of 1. In FIG. 4, the abscissa represents a location on the line starting from the F point, passing through the M point and the K point, and returning to the F point in FIG. 2.

As illustrated in FIG. 4, a photonic band gap for TM-polarized light exists within the wavelength a/λ range of about 0.4-0.5. For this reason, when the period a is 257 nm, light containing TM-polarized light is not generated from excitons within the wavelength λ range of 514-642 nm. Therefore, the fluorescent material layer 105 emits only TE-polarized yellow light as fluorescence.

As described above, in order to generate blue light and yellow light which have a high TE-polarized light ratio, the light emitting device of this embodiment functions as a light source emitting white light with a high TE-polarized light ratio.

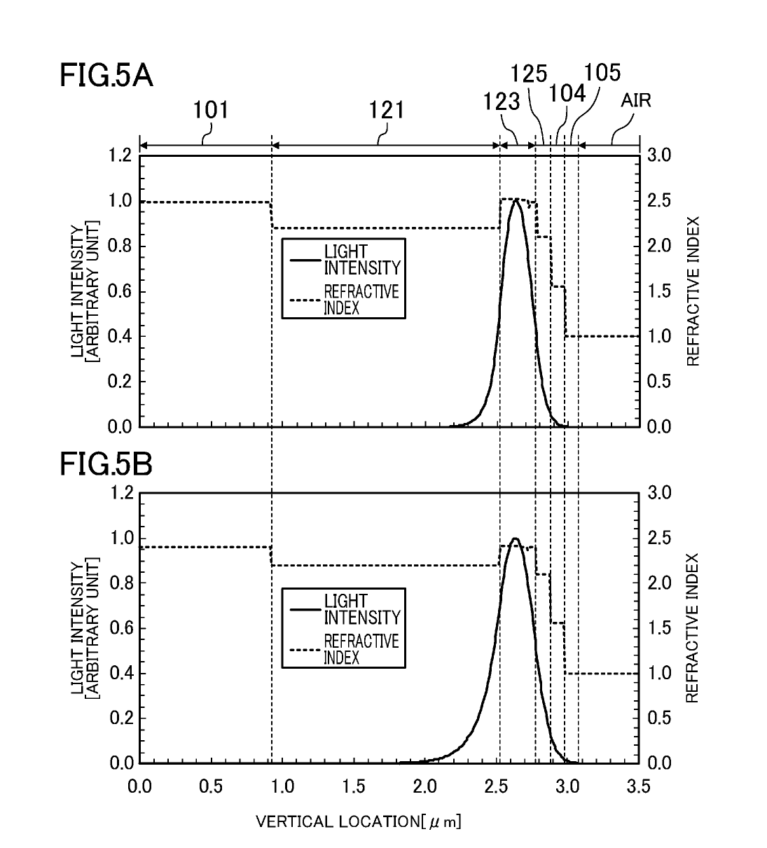

The light emitting device of this embodiment includes an optical waveguide providing optical waveguide performance also for yellow light. FIG. 5A illustrates a result of calculating the distribution of light with a wavelength of 440 nm in a direction in which the constituent layers of the semiconductor multilayer film 102 are laminated by transfer matrix, and FIG. 5B illustrates a result of calculating the distribution of light with a wavelength of 570 nm in the direction by transfer matrix. The cylindrical portions of the fluorescent material layer 105 are arranged to have a value r/a of 0.25. Thus, in the calculations, approximate values obtained by considering the fluorescent material layer 105 as a homogeneous layer having an effective volume filling factor of 55.5% and an average refractive index of 1.56 were used. The light emitting device of this embodiment includes the n-type cladding layer 121 made of Al_{0.8}In_{0.2}N which is lattice matched to GaN, and has a refractive index of 2.2 and a refractive index difference of 0.3 from the refractive index of GaN. Thus, as illustrated in FIG. 5, light with both wavelengths of 440 nm and 570 nm can be strongly confined in the lamination direction in which the constituent layers of the semiconductor multilayer film 102 are laminated. When the radiation angle at which light is radiated from the optical waveguide end face was calculated based on the light distribution in the lamination direction illustrated in FIG. 5, the full width at half maximum θ v of the vertical far field distribution was about 54° at a wavelength of 440 nm and about 50° at a wavelength of 570 nm. The values show that the light emitting device of this embodiment has sufficiently narrower beam divergence than a usual LED.

When a horizontal refractive index variation An was calculated using an effective index method, the horizontal refractive index variation An was 5.06×10⁻³ at a wavelength of 440 nm and 1.10×10⁻² at a wavelength of 570 nm. When the full width at half maximum Oh of the horizontal far field distribution in the light emitting device including an optical waveguide with a width of 4 μm was calculated based on the obtained horizontal refractive index variation An, the full width at half maximum Oh was about 6° at a wavelength of 440 nm and about 7° at a wavelength of 570 nm. The values show that the light emitting device of this embodiment has much narrower beam divergence than a usual LED.

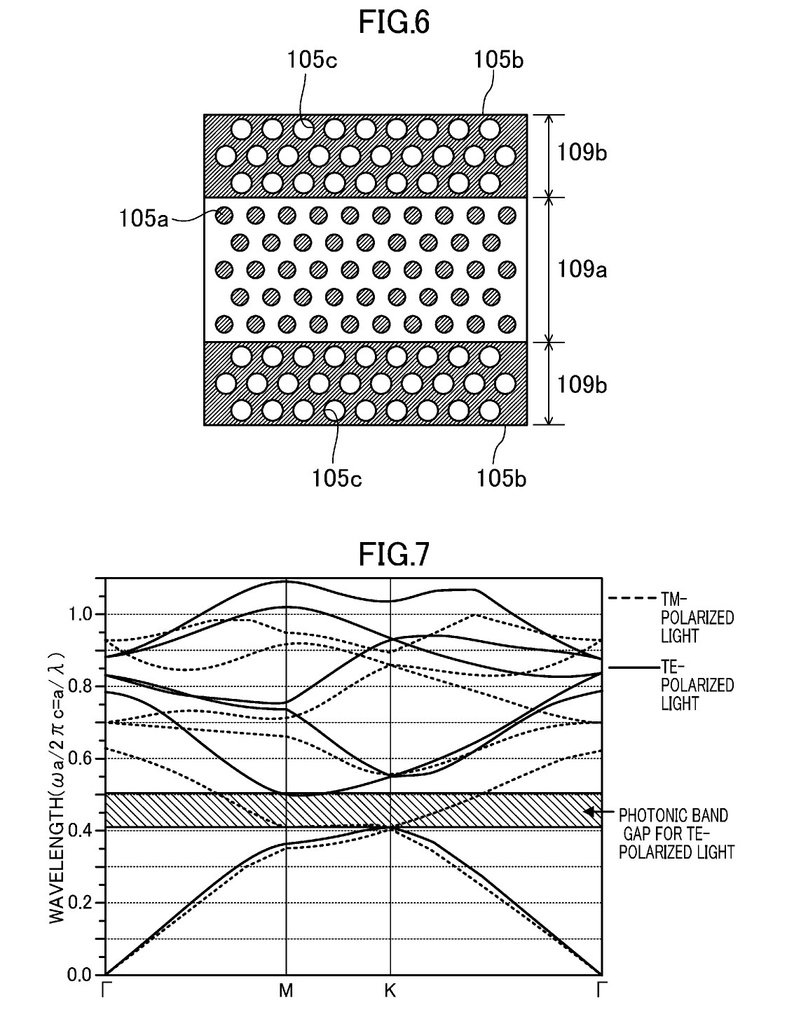

In this embodiment, the cylindrical portions of the fluorescent material layers 105 are arranged on a region serving as an optical waveguide to have a uniform two-dimensional (refractive index) periodic structure. However, as illustrated in FIG. 6, cylindrical portions of a fluorescent material layer 105a formed on a central portion 109a of the optical waveguide, and fluorescent material layers 105b formed on outer portions 109b thereof may be arranged to have different periodic structures. In FIG. 6, the cylindrical portions of the fluorescent material layer 105a having a diameter 2 r of 128.5 nm are arranged on an about 2.8-μm-wide region corresponding to the central portion 109a of the optical waveguide to form a triangular lattice with a period a of 257 nm. In contrast, the fluorescent material layers 105b are formed on about 0.8-μm-wide regions corresponding to the outer portions 109b of the optical waveguide to each have openings 105c each having a diameter of 210.7 nm and forming a triangular lattice with a period a of 257 nm. The directions from the Γ point toward the M points in the first Brillouin zones of the corresponding triangular lattices coincide with the direction in which the groove extends. The fluorescent material layer 105a may have openings, and the fluorescent material layers 105b may each have cylindrical portions formed on the outer portions 109b of the optical waveguide.

FIG. 7 illustrates results of determining the photonic band structure of each of the outer portions 109b by calculation. As illustrated in FIG. 7, in the outer portion 109b, a photonic band gap for TE-polarized light exists within the wavelength a/λ range of about 0.4-0.5. Thus, when the period a is 257 nm, TE-polarized guided light is totally reflected back internally within the wavelength λ range of 514-642 nm even with incidence of the light on the outer portions 109b of the optical waveguide at any angle. Therefore, TE-polarized yellow light emitted from the fluorescent material layer 105 is confined in the optical waveguide 109, and hardly leaks laterally from the optical waveguide 109. As a result, the luminous efficacy of yellow light can be further increased.

An example in which the central portion 109a and each of the outer portions 109b form different two-dimensional periodic structures by allowing the shape of the fluorescent material layer 105a formed on the central portion 109a to be different from the shape of each of the fluorescent material layers 105b formed on the outer portion 109b was described. However, the fluorescent material layer 105a and the fluorescent material layers 105b may have cylindrical portions. In this case, the period a of the cylindrical portions of the fluorescent material layer 105a and the period a of the cylindrical portions of each of the fluorescent material layers 105b which are each a base unit forming the corresponding two-dimensional periodic structure may be different from each other, and alternatively, the radius r of each of the cylindrical portions of the fluorescent material layer 105a and the radius r of each of the cylindrical portions of the fluorescent material layers 105b which are each a base unit forming the corresponding period may be different from each other. Alternatively, the periods a may be different from each other, and the radii r may be different from each other. The fluorescent material layer 105a and the fluorescent material layers 105b may have openings.

In this embodiment, the two-dimensional periodic structure was described as a triangular lattice tending to exhibit a photonic band gap; however, the two-dimensional periodic structure is not limited to the triangular lattice, and as long as a predetermined photonic band gap can be formed, any periodic structure may be used. Specifically, the periodic structure may form, e.g., a tetragonal lattice or an orthorhombic lattice.

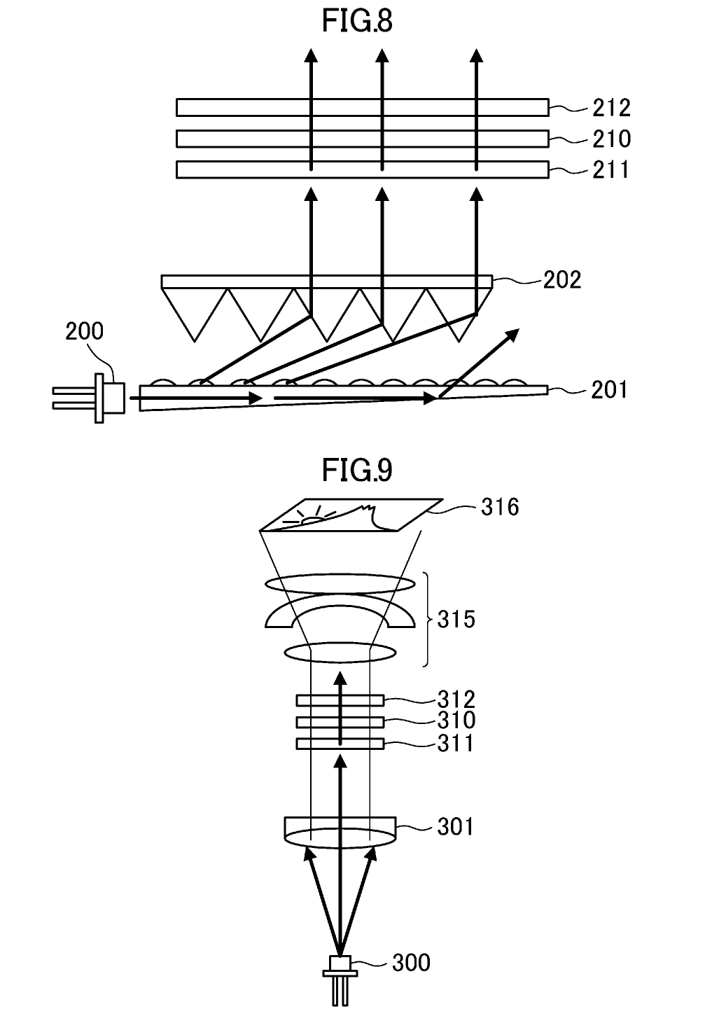

FIG. 8 illustrates an example in which a light emitting device 200 of this embodiment is used as a backlight for a liquid crystal panel 210. Light exiting from the light emitting device 200 travels through the interior of a light guide plate 201, exits in a predetermined direction, and enters a total internal reflection prism 202. The light refracted in a direction perpendicular to the liquid crystal panel 210 by the total internal reflection prism 202 passes through an entry-side polarizing plate 211, the liquid crystal panel 210, and an exit-side polarizing plate 212.

The full width at half maximum radiation angle of a conventional LED is about 120°, and thus, the coupling efficiency between the LED and a light guide plate is low. In contrast, the full width at half maximum Oh of the horizontal far field distribution in the light emitting device of this embodiment is very narrow, such as about 6-7°, and the full width at half maximum θ v of the vertical far field distribution therein is about 50-54°. Thus, when the direction horizontal to the light emitting device 200 is matched with the direction perpendicular to the light guide plate 201, and the direction perpendicular to the light emitting device 200 is matched with the direction horizontal to the light guide plate 201, this increases the coupling efficiency between the light emitting device 200 and the light guide plate 201. Furthermore, light can be diffused into a wide region of the surface of the light guide plate 201.

About 50% of white light generated by the LED is removed by a polarizing plate disposed at the entry side of a liquid crystal panel. However, light emitted from the light emitting device 200 of this embodiment has a high TE-polarized light ratio, and thus, when the polarization direction in which the light passes through the polarizing plate is matched with the TE polarization direction of the light emitting device 200, the amount of the light components removed by the polarizing plate 211 is small, and thus, the efficiency of light utilization can be enhanced.

FIG. 9 illustrates an example in which a light emitting device 300 of this embodiment is used as a light source for a projector. Light exiting from the light emitting device 300 is collimated into parallel light by a collimator lens 301, and then the parallel light passes through an entry-side polarizing plate 311, a liquid crystal panel 310, and an exit-side polarizing plate 312. The light passing through them is magnified by an optical system 315, and is projected onto a screen 316.

The full width at half maximum radiation angle of the conventional LED is large, such as about 120°, and the light radiation area onto which light is radiated is also large. Thus, a large lens needs to be used as a collimator lens. However, the radiation angle of the light emitting device of this embodiment is up to about 50-54°, and the light radiation area is also small. Thus, even with a reduction in the size of the collimator lens 301, light can be efficiently collimated. About 50% of white light generated by the LED is removed by a polarizing plate disposed at the entry side of a liquid crystal panel. However, since light emitted from the light emitting device 300 of this embodiment has a high TE-polarized light ratio, the amount of the light components removed by the polarizing plate 311 is small, and thus, the efficiency of light utilization can be enhanced.

In this embodiment, a white light emitting device using a blue SLD made of a GaN-based semiconductor multilayer film, and a yellow fluorescent material made of YAG:Ce was described. However, the light emitting device is not limited to the white light emitting device, and may have any other configurations, or may be made of any other materials. For example, also when a combination of a blue laser diode made of a GaN-based semiconductor multilayer film and green and red fluorescent materials, or a combination of an ultraviolet SLD made of a GaN-based semiconductor multilayer film and blue, green, and red fluorescent materials is used to form a white light emitting device, a similar process can be used.

Not only the white light emitting device, but also a light emitting device into which a waveguide light emitting device and a fluorescent material are integrated can be used to control the polarization direction of light emitted from the fluorescent material. Therefore, the semiconductor multilayer film is not limited to the GaN-based film, and a red or infrared light emitting device using, e.g., an AlInGaP-based or AlGaAs-based semiconductor multilayer film may be combined with a fluorescent material. Furthermore, instead of a material, such as YAG:Ce, obtained by doping an oxide with a rare-earth element, e.g., organic dye, a polymer throughout which semiconductor nanoparticles made of, e.g., ZnS or CdSe are dispersed, or oxide glass may be used as the fluorescent material.

The light emitting device of the present disclosure which is used as a light source device provides high efficiency of emitted light utilization, and is useful for, in particular, light sources for, e.g., a backlight and a projector.

What is claimed is:

1. A light emitting device comprising:
a semiconductor multilayer film formed on a principal surface of a substrate, and including an active layer configured to generate light at a first wavelength; and
a fluorescent material layer formed on the semiconductor multilayer film, and forming a first two-dimensional periodic structure, wherein
the fluorescent material layer generates light at a second wavelength by being excited by the first wavelength light,
the semiconductor multilayer film has an optical waveguide through which the first wavelength light and the second wavelength light are guided, and
the first wavelength light and the second wavelength light which are radiated from an end face of the optical waveguide include a higher proportion of light having an electric field oriented in a direction horizontal to the principal surface than a proportion of light having an electric field oriented in a direction perpendicular to the principal surface.

2. The light emitting device of claim 1, wherein
the first two-dimensional periodic structure forms a photonic band gap for the second wavelength light having an electric field oriented in a direction perpendicular to the principal surface.

3. The light emitting device of claim 1, wherein
a portion of the fluorescent material layer formed over a central portion of the optical waveguide forms the first two-dimensional periodic structure,
a portion of the fluorescent material layer formed over an outer portion of the optical waveguide forms a second two-dimensional periodic structure, and
periods of the first and second two-dimensional periodic structures, or sizes or shapes of base units forming the periodic structures are different from each other.

4. The light emitting device of claim 3, wherein
the second two-dimensional periodic structure forms a photonic band gap for the second wavelength light having an electric field oriented in a direction parallel to the principal surface.

5. The light emitting device of claim 1, further comprising:
a transparent electrode formed between the semiconductor multilayer film and the fluorescent material layer.
